(19) United States
(12) Patent Application Publication
(10) Pub. No.: US 2026/0231518 A1
(43) Pub. Date: Aug. 6, 2026

(54) CROSS-COUPLE GATE INPUT CONNECTIONS IN COMPLEMENTARY FIELD-EFFECT TRANSISTOR CELL ARCHITECTURE

(71) Applicant: QUALCOMM Incorporated, San Diego, CA (US)

(72) Inventors: Shreesh NARASIMHA, Charlotte, NC (US); Yan SUN, San Diego, CA (US); Raheel AZMAT, Cork (IE)

(21) Appl. No.: 19/046,953

(22) Filed: Feb. 6, 2025

(51) Int. Cl. H10D 84/85; H01L 23/528; H10D 30/00; H10D 30/43; H10D 30/47; H10D 30/62; H10D 62/10; H10D 62/13; H10D 64/23; H10D 64/27

(52) U.S. Cl. CPC H10D 84/851; H10D 30/43; H10D 30/481; H10D 30/501; H10D 30/6219; H10D 62/121; H10D 62/151; H10D 64/251; H10D 64/512; H10D 64/514; H10D 84/853; H10W 20/435

(57) ABSTRACT

A chip includes a first source/drain, a second source/drain, a top gate disposed between the first source/drain and the second source/drain, and one or more first channels coupled between the first source/drain and the second source/drain, wherein the one or more first channels pass through the top gate. The chip also includes a third source/drain, wherein the third source/drain is vertically stacked with the first source/drain, a fourth source/drain, wherein the fourth source/drain is vertically stacked with the second source/drain, and a first insulator disposed below the top gate and between the third source/drain and the fourth source/drain, wherein the first insulator electrically isolates the top gate from the third source/drain and the fourth source/drain.

### BACKGROUND

### Field

Aspects of the present disclosure relate generally to chip layout, and more particularly, to complementary field-effect transistors (CFETs).

### Background

A chip includes many transistors for performing various functions on the chip. The transistors may include p-type field-effect transistors (PFETs) and n-type field-effect transistors (NFETs). PFETs and NFETs on the chip may be used in combination to provide complementary field-effect transistors (CFETs), which may be used in various circuits on the chip, including, for example, logic gates and flip-flops.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first source/drain, a second source/drain, a top gate disposed between the first source/drain and the second source/drain, and one or more first channels coupled between the first source/drain and the second source/drain, wherein the one or more first channels pass through the top gate. The chip also includes a third source/drain, wherein the third source/drain is vertically stacked with the first source/drain, a fourth source/drain, wherein the fourth source/drain is vertically stacked with the second source/drain, and a first insulator disposed below the top gate and between the third source/drain and the fourth source/drain, wherein the first insulator electrically isolates the top gate from the third source/drain and the fourth source/drain.

A second aspect relates to a chip. The chip includes a top gate, a first insulator disposed below the top gate, a bottom gate, a second insulator disposed above the bottom gate, and a common gate. The chip also includes a first source/drain disposed between the top gate and the common gate, a second source/drain disposed between the common gate and the second insulator, and one or more first channels coupled between the first source/drain and the second source/drain, wherein the one or more first channels pass through the common gate. The chip also includes a third source/drain disposed between the first insulator and the common gate, wherein the third source/drain is stacked vertically with the first source/drain, a fourth source/drain disposed between the common gate and the bottom gate, wherein the fourth source/drain is stacked vertically with the second source/drain, and one or more second channels coupled between the third source/drain and the fourth source/drain, wherein the one or more second channels pass through the common gate.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary layout of diffusion regions and gates for providing complementary transistors according to certain aspects of the present disclosure.

FIG. 3A shows a perspective view of an exemplary complementary field-effect transistor (CFET) structure according to certain aspects of the present disclosure.

FIG. 3B shows a perspective view of the CFET structure of FIG. 3A in which gates of the CFET structure are shown in phantom according to certain aspects of the present disclosure.

FIG. 4A shows a circuit schematic of an exemplary structure in which the structure is used to implement an inverter multiplexer according to certain aspects of the present disclosure.

FIG. 4B shows an example in which the structure of FIG. 4A is used to implement an XOR gate according to certain aspects of the present disclosure.

FIG. 5 shows an example in which gates in the exemplary layout of FIG. 2 are cut to implement cross-couple gate inputs according to certain aspects of the present disclosure.

FIG. 6A shows a top view of a CFET structure including diffusion breaks according to certain aspects of the present disclosure.

FIG. 6B shows a bottom view of the CFET structure of FIG. 6A according to certain aspects of the present disclosure.

FIG. 7 shows a perspective view of a CFET structure including a bottom gate, a first insulator disposed above the bottom gate, a top gate, and a second insulator disposed below the top gate according to certain aspects of the present disclosure.

FIG. 8A shows a top view of the CFET structure of FIG. 7 according to certain aspects of the present disclosure.

FIG. 8B shows a bottom view of the CFET structure of FIG. 7 according to certain aspects of the present disclosure.

FIG. 9 shows a cross-sectional view of an example of a first jumper and a second jumper coupled to the CFET structure of FIG. 7 according to certain aspects of the present disclosure.

FIG. 10A shows a cross-sectional view of an exemplary structure configured to couple a source/drain in FIG. 9 to an output according certain aspects of the present disclosure.

FIG. 10B shows a cross-sectional view of an exemplary structure configured to couple another source/drain in FIG. 9 to the output according certain aspects of the present disclosure.

FIG. 11 shows a cross-sectional view of another example of a first jumper and a second jumper coupled to the CFET structure of FIG. 7 according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

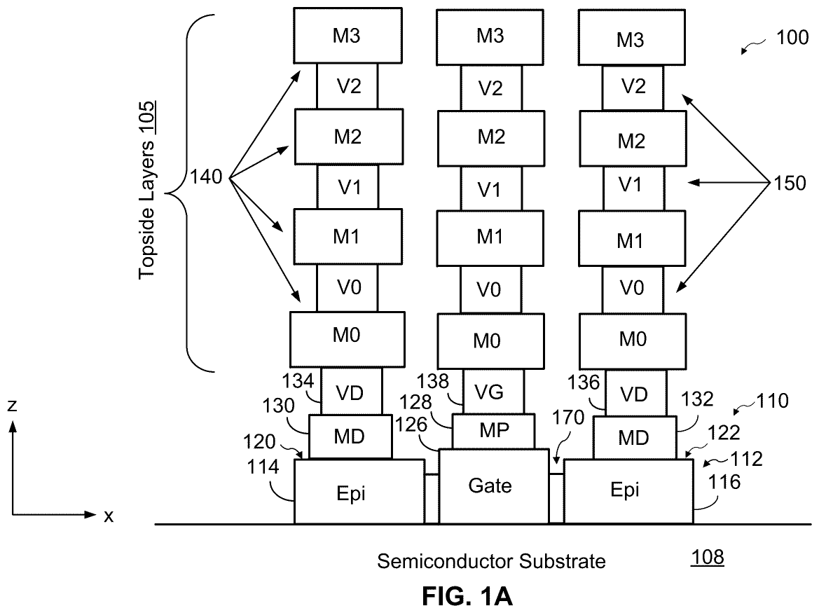

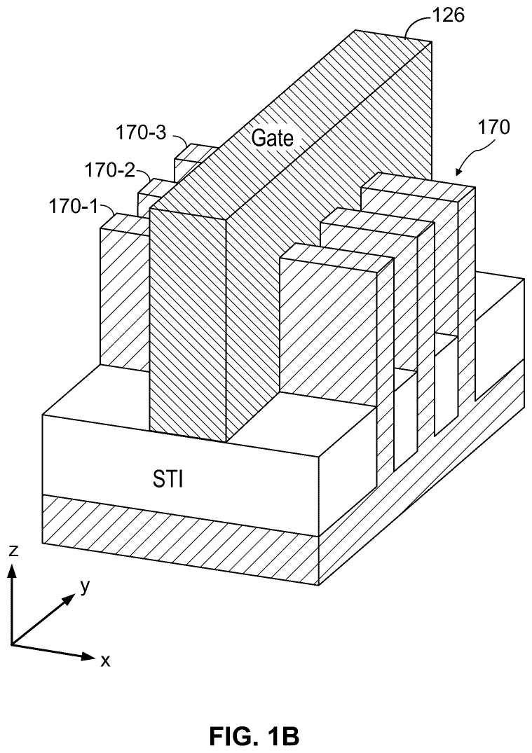

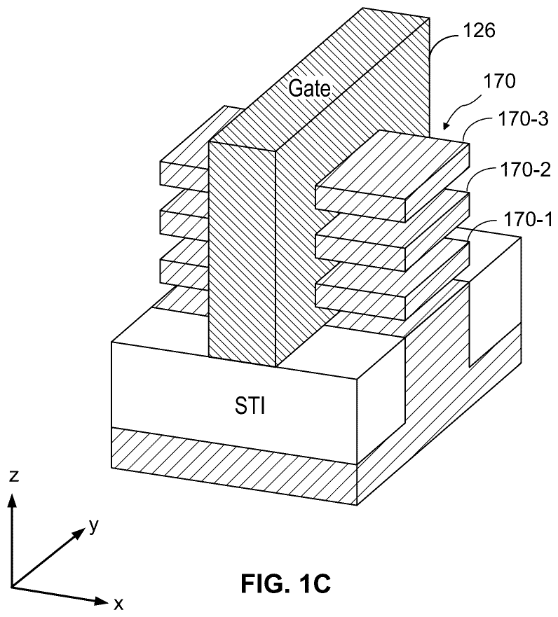

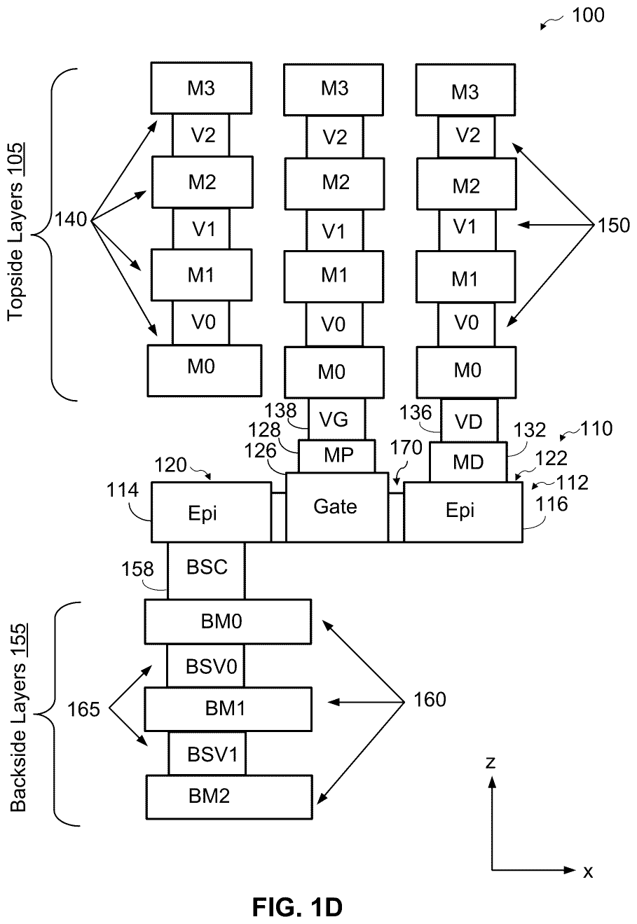

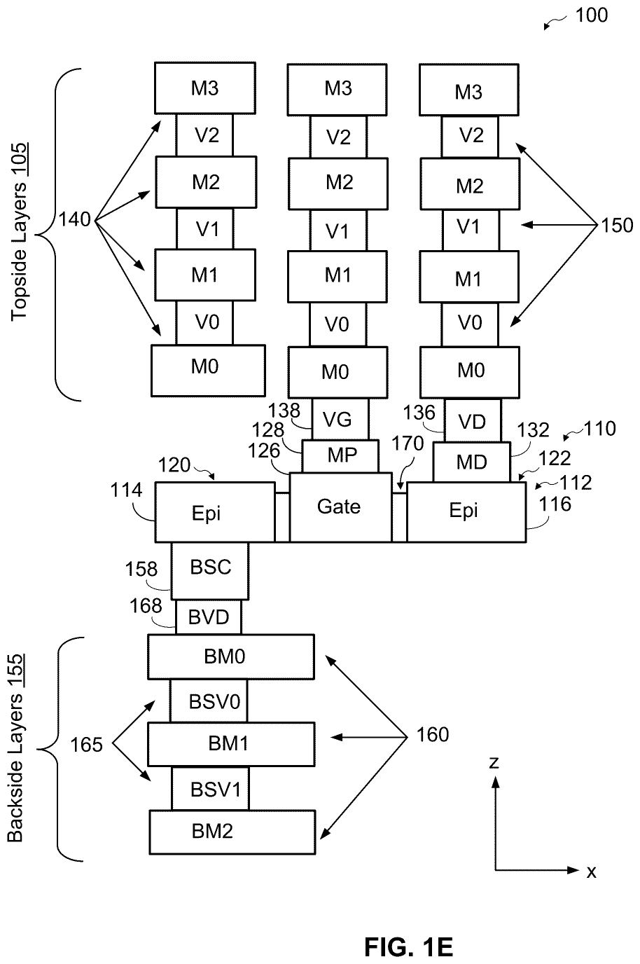

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor. For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between devices on the chip 100. In some implementations, the STI may be omitted.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V2. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the first contact 130 and metal layer M0, in which the via 134 couples the first contact 130 to metal layer M0. The chip 100 also includes a via 136 disposed between the second contact 132 and metal layer M0, in which the via 136 couples the second contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

The transistors on the chip 100 may include p-type field-effect transistors (PFETs) and n-type field-effect transistors (NFETs). The PFETs and NFETs may be implemented using a gate-all-around field effect transistor (FET) process (e.g., the exemplary gate-all-around FET shown in FIG. 1C), a fin field-effect transistor (FinFET) process (e.g., the exemplary FinFET shown in FIG. 1B), or another type of process.

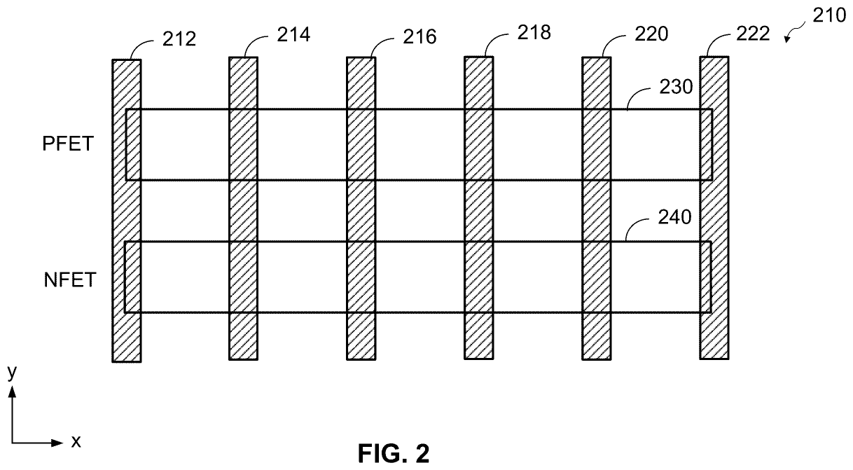

A PFET and an NFET may be placed side by side on the chip 100 to provide complementary transistors. In this regard, FIG. 2 shows a top view of an exemplary layout 210 providing complementary transistors according to certain aspects of the present disclosure. In this example, the layout 210 includes a first diffusion region 230 and a second diffusion region 240 extending in the x direction, in which the first diffusion region 230 and the second diffusion region 240 are placed (i.e., laid) side by side in the y direction. The first diffusion region 230 may be a p-type diffusion region to provide one or more PFETs and the second diffusion region 240 may be an n-type diffusion region to provide one or more NFETs, as discussed further below. Each of the diffusion regions 230 and 240 may include epi layers (e.g., instances of the epi layers 114 and 116) and channels (e.g., instances of the one or more channels 170). For ease of illustration, FIG. 2 depicts each of the diffusion regions 230 and 240 as a rectangle indicating the general area of the diffusion region with the details of the diffusion regions 230 and 240 omitted.

The layout 210 also includes gates 212, 214, 216, 218, 220, and 222 extending in the y direction and spaced apart from one another in the x direction (e.g., by a uniform pitch). Each of the gates 212, 214, 216, 218, 220, and 222 may include a gate metal (e.g., a HKMG), polysilicon, and/or another gate material. In this example, the first diffusion region 230 (which is p-type in this example) and the gates 212, 214, 216, 218, 220, and 222 provide the one or more PFETs, and the second diffusion region 240 (which is n-type in this example) and the gates 212, 214, 216, 218, 220, and 222 provide the one or more NFETs. In the example shown in FIG. 2, the gates 212, 214, 216, 218, 220, and 222 are shared by the one or more PFETs and the one or more NFETs. In other examples, one or more of the gates 212, 214, 216, 218, 220, and 222 may be cut between the first diffusion region 230 and the second diffusion region 240 to provide separate gate connections for the one or more PFETs and the one or more NFETs to realize various logic functions, as discussed further below.

FIG. 2 show an example in which the one or more PFETs and the one or more NFETs are placed (i.e., laid) side by side on the chip 100. In other examples, the chip 100 may include a PFET and an NFET that are stacked vertically in the z direction instead of laid side by side. Stacking the PFET and the NFET vertically reduces cell height in the y direction compared with the side-by-side layout 210 illustrated in FIG. 2. The reduced cell height allows a larger number of cells to be placed on the chip 100.

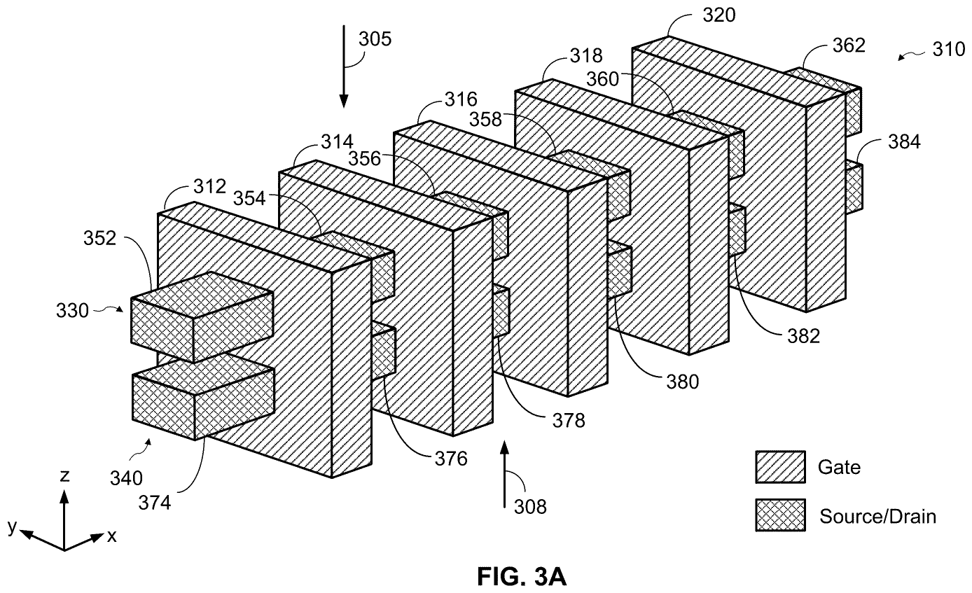

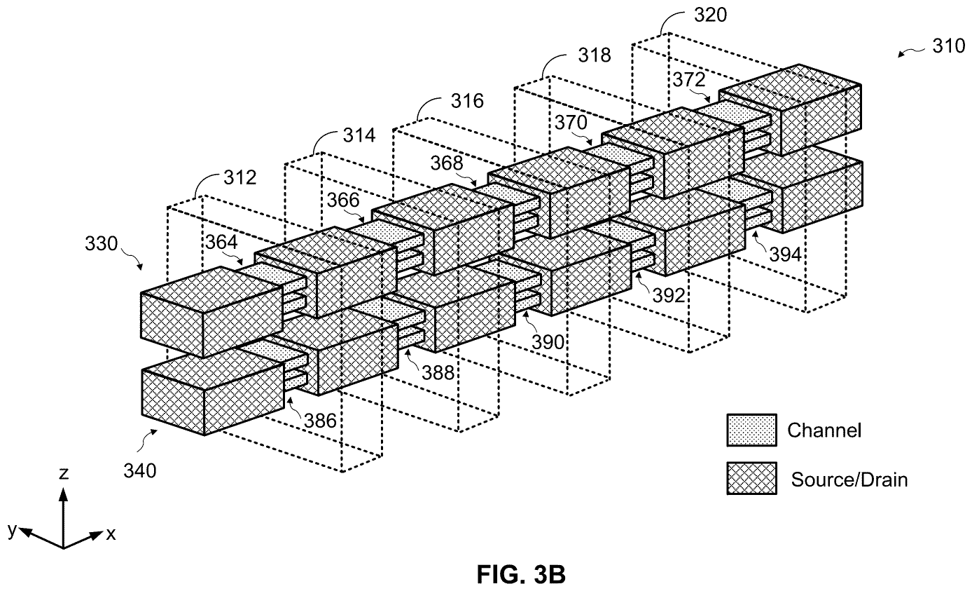

In this regard, FIG. 3A shows a perspective view of a complementary field-effect transistor (CFET) structure 310 with a stacked P-N architecture according to certain aspects. As discussed further below, the CFET structure 310 provides stacked complementary transistors.

The CFET structure 310 includes a first diffusion region 330 extending in the x direction and a second diffusion region 340 extending in the x direction. The first diffusion region 330 and the second diffusion region 340 are stacked vertically in the z direction, in which the first diffusion region 330 and the second diffusion region 340 are spaced apart in the z direction. In the example in FIG. 3A, the first diffusion region 330 and the second diffusion region 340 are aligned in the y direction. The first diffusion region 330 may be a p-type diffusion region and the second diffusion region 340 may be an n-type diffusion region to provide complementary transistors. However, it is to be appreciated that the present disclosure is not limited to this example. In other implementations, the first diffusion region 330 may be an n-type diffusion region and the second diffusion region 340 may be a p-type diffusion region.

The CFET structure 310 also includes gates 312, 314, 316, 318, and 320 where each of the gates 312, 314, 316, 318, and 320 extends in the y direction and the z direction. The gates 312, 314, 316, 318, and 320 are spaced apart from one another in the x direction (e.g., by a uniform pitch). Each of the gates 312, 314, 316, 318, and 320 may include a gate metal (e.g., HKMG), polysilicon, and/or another gate material. It is to be appreciated that the positions of the diffusion regions 330 and 340 with respect to the gates 312, 314, 316, 318, and 320 in the y direction and the z direction are not limited to the example shown in FIG. 3A. It is also to be appreciated that the shapes of the diffusion regions 330 and 340 are not limited to the example shown in FIG. 3A and that the shapes of the diffusion regions 330 and 340 may take on many different forms.

In the example in FIG. 3A, the first diffusion region 330 includes a source/drain 352 to the left of the gate 312 in the x direction, a source/drain 354 between the gates 312 and 314, a source/drain 356 between the gates 314 and 316, a source/drain 358 between the gates 316 and 318, a source/drain 360 between the gates 318 and 320, and a source/drain 362 to the right of the gates 320 in the x direction. Each source/drain may include a respective epitaxial (epi) layer (e.g., instance of the epi layer 114 or 116).

Referring to FIG. 3B (which shows the gates 312, 314, 316, 318, and 320 in phantom), the first diffusion region 330 also includes one or more channels 364 coupled between the source/drain 352 and the source/drain 354 and passing through the gate 312, one or more channels 366 coupled between the source/drain 354 and the source/drain 356 and passing through the gate 314, one or more channels 368 coupled between the source/drain 356 and the source/drain 358 and passing through the gate 316, one or more channels 370 coupled between the source/drain 358 and the source/drain 360 and passing through the gate 318, and one or more channels 372 coupled between the source/drain 360 and the source/drain 362 and passing through the gate 320. Each of the one or more channels may include one or more nanosheets or another type of channel. In this example, the first diffusion region 330 and the gates 312, 314, 316, 318, and 320 provide one or more PFETs. However, it is to be appreciated that the first diffusion region 330 and the gates 312, 314, 316, 318, and 320 may provide one or more NFETs in other implementations.

The second diffusion region 340 includes a source/drain 374 to the left of the gate 312 in the x direction, a source/drain 376 between the gates 312 and 314, a source/drain 378 between the gates 314 and 316, a source/drain 380 between the gates 316 and 318, a source/drain 382 between the gates 318 and 320, and a source/drain 384 to the right of the gates 320 in the x direction. Each source/drain may include a respective epitaxial (epi) layer (e.g., instance of the epi layer 114 or 116).

Referring to FIG. 3B, the second diffusion region 340 also includes one or more channels 386 coupled between the source/drain 374 and the source/drain 376 and passing through the gate 312, one or more channels 388 coupled between the source/drain 376 and the source/drain 378 and passing through the gate 314, one or more channels 390 coupled between the source/drain 378 and the source/drain 380 and passing through the gate 316, one or more channels 392 coupled between the source/drain 380 and the source/drain 382 and passing through the gate 318, and one or more channels 394 coupled between the source/drain 382 and the source/drain 384 and passing through the gate 320. Each of the one or more channels may include one or more nanosheets or another type of channel. In this example, the second diffusion region 340 and the gates 312, 314, 316, 318, and 320 provide one or more NFETs. However, it is to be appreciated that the second diffusion region 340 and the gates 312, 314, 316, 318, and 320 may provide one or more PFETs in other implementation.

In this example, the gates 312, 314, 316, 318, and 320 are shared by the one or more PFETs and the one or more NFETs in the CFET structure 310. As discussed further below, the shared gates make it challenging to implement logic gates with cross-couple gate inputs using the CFET structure 310.

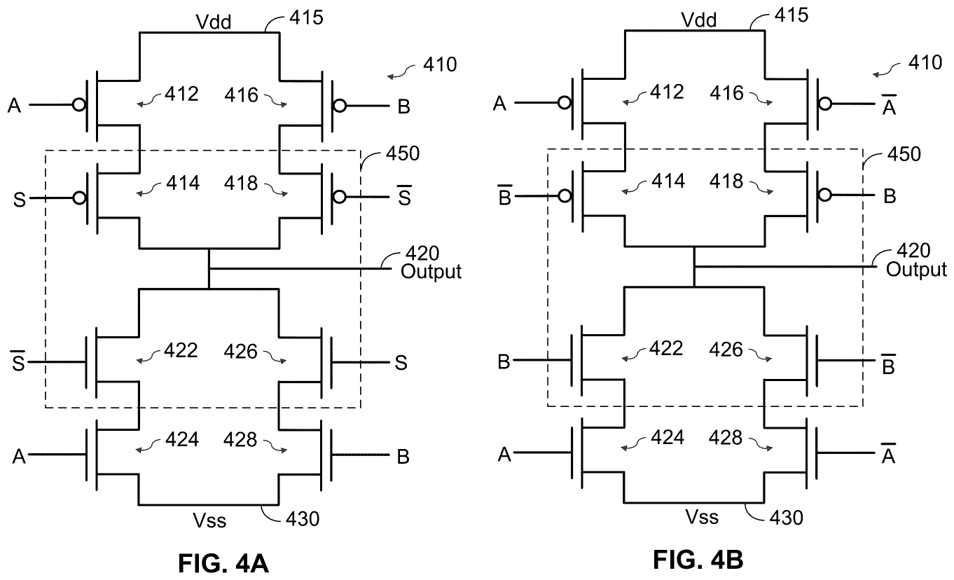

FIG. 4A show an exemplary logic gate structure 410 with cross-couple gate inputs according to certain aspects. The structure 410 may be used to realize an inverter multiplexer, an XOR gate, a XNOR gate, or another logic gate.

In this example, the structure 410 includes a first PFET 412, a second PFET 414, a third PFET 416, and a fourth PFET 418. The first PFET 412 and the second PFET 414 are coupled in series between the supply rail 415 and the output 420. The third PFET 416 and the fourth PFET 418 are coupled in series between the supply rail 415 and the output 420.

The structure 410 also includes a first NFET 422, a second NFET 424, a third NFET 426, and a fourth NFET 428. The first NFET 422 and the second NFET 424 are coupled in series between the output 420 and a low rail 430 (e.g., ground rail). The third NFET 426 and the fourth NFET 428 are coupled in series between the output 420 and the low rail 430 (ground rail). As used herein, a low rail is a rail having a lower potential than the supply rail 415, which has a supply voltage Vdd.

FIG. 4A shows an example in which the structure 410 is used to implement an inverter multiplexer configured to select a first input A or a second input B based on a select signal. In this example, the first input A is coupled to the gate of the first PFET 412 and the gate of the second NFET 424. Since the first PFET 412 and the second NFET 424 are both coupled to the first input A, the first PFET 412 and the second NFET 424 may share a gate. The second input B is coupled to the gate of the third PFET 416 and the gate of the fourth NFET 428. Since the third PFET 416 and the fourth NFET 428 are both coupled to the second input B, the third PFET 416 and the fourth NFET 428 may share a gate.

The select signal is received at a select input S and the inverse of the select signal is received at an inverse select input S̅. In this example, the select input S is coupled to the gate of the second PFET 414 and the gate of the third NFET 426 and the inverse select input S̅ is coupled to the gate of the first NFET 422 and the gate of fourth PFET 418. As shown in FIG. 4A, the select input S and the inverse select input S̅ are cross coupled to the gates of the PFETs 414 and 418 and the gates of the NFETs 422 and 426. In FIG. 4A, the dashed box 450 indicates the transistors with the cross-couple gate inputs (i.e., the PFETs 414 and 418 and the NFETs 422 and 426 in this example).

FIG. 4B shows an example in which the structure 410 is used to implement an XOR gate configured to perform an XOR operation on the first input A and the second input B. In this example, the first input A is coupled to the gate of the first PFET 412 and the gate of the second NFET 424. Since the first PFET 412 and the second NFET 424 are both coupled to the first input A, the first PFET 412 and the second NFET 424 may share a gate. The inverse of the first input Ā is coupled to the gate of the third PFET 416 and the gate of the fourth NFET 428. Since the third PFET 462 and the fourth NFET 428 are both coupled to the inverse of the first input Ā, the third PFET 416 and the fourth NFET 428 may share a gate.

The inverse of the second input B̅ is coupled to the gate of the second PFET 414 and the gate of the third NFET 426 and the second input B is coupled to the gate of the first NFET 422 and the gate of the fourth PFET 418. As shown in FIG. 4B, the second input B and the inverse of the second input B̅ are cross coupled to the gates of the PFETs 414 and 418 and the gates of the NFETs 422 and 426.

The exemplary structure 410 may also be used to implement an XNOR gate with cross-couple gate inputs. Thus, the exemplary structure 410 may be used to implement various types of logic gates with cross-couple gate inputs.

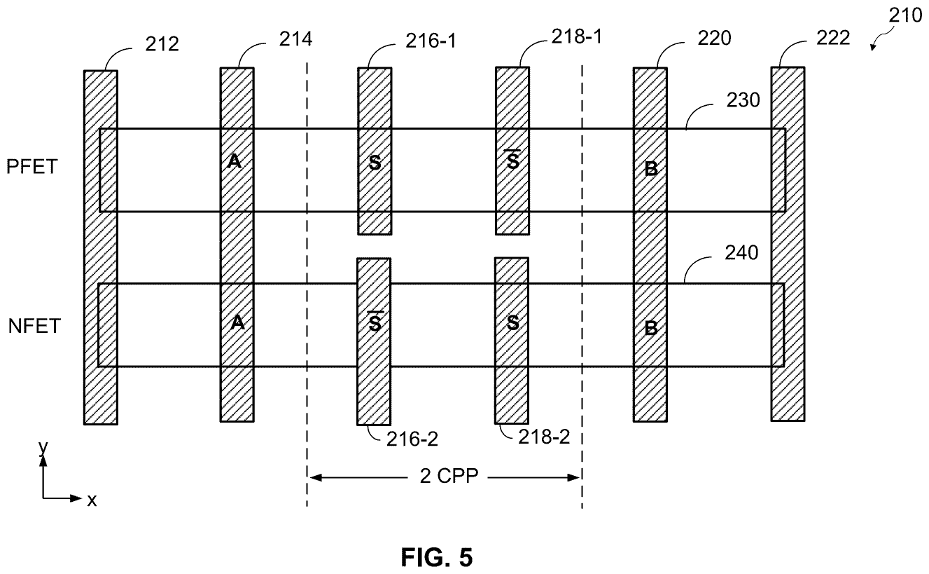

FIG. 5 shows an example in which the structure 410 is implemented using the exemplary side-by-side layout 210. In this example, the structure 410 is configured to implement the inverter multiplexer shown in FIG. 4A.

In the example shown in FIG. 5, the gate 214 is coupled to the first input A and provides the shared gate for the first PFET 412 and the second NFET 424. The gate 220 is coupled to the second input B and provides the shared gate for the third PFET 416 and the fourth NFET 428. To implement the cross-couple gate inputs for the select input S and the inverse select input S̅, the gate 216 in FIG. 2 is cut between the first diffusion region 230 and the second diffusion region 240 into separate gates 216-1 to 216-2. Similarly, the gate 218 in FIG. 2 is cut between the first diffusion region 230 and the second diffusion region 240 into separate gates 218-1 to 218-2. The gates 216 and 218 may be cut using known lithographic and etching processes.

In this example, the gate 216-1 is coupled to the select input S and provides the gate of the second PFET 414. The gate 216-2 is coupled to the inverse select input S̅ and provides the gate of the first NFET 422. The gate 218-1 is coupled to the inverse select input S̅ and provides the gate of the fourth PFET 418. The gate 218-2 is coupled to the select input S and provides the gate of the third NFET 426.

Thus, cross-couple gate inputs may be implemented in the side-by-side layout 210 using gate cuts (e.g., for implementing an inverter multiplexer, an XOR gate, an XNOR gate, etc.). The gate cuts may be performed using known lithographic and etching processes. In the example in FIG. 5, the cross-couple gate inputs for the PFETs 414 and 418 and the NFETs 422 and 426 need a length of two contacted poly pitch (2CPP) in the side-by-side layout 210, where one CPP is the pitch between adjacent gates in the x direction.

As discussed above, the gates 312, 314, 316, 318, and 320 in the CFET structure 310 are shared by the one or more PFETs and the one or more NFETs in the CFET structure 310. The shared gates make it challenging to implement logic gates with cross-couple gate inputs using the CFET structure 310. Gate cutting processes used for cutting gates in the side-by-side layout 210 etch the gates vertically from the top and/or the bottom, which is suitable for cutting the gates between diffusion regions that are laid side by side. However, since the first diffusion region 330 and the second diffusion region 340 are vertically stacked in the CFET structure 310, these gate cutting processes are not suitable for cutting gates between the first diffusion region 330 and the second diffusion region 340 in the CFET structure 310. As used herein, “vertically stacked” means stacked in the z direction.

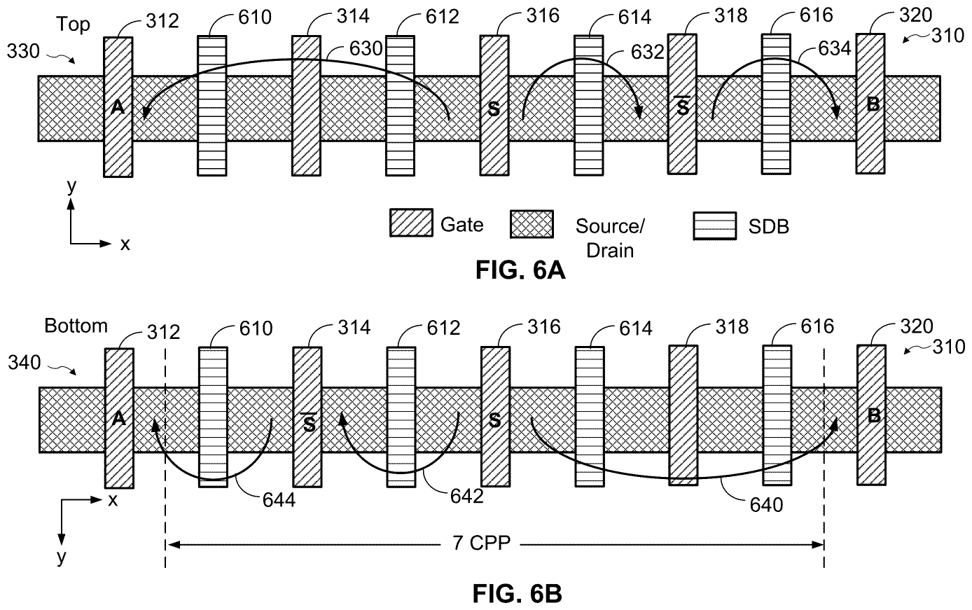

FIGS. 6A and 6B illustrate one approach for implementing cross-couple gate inputs in the CFET structure 310 using diffusion breaks according to certain aspects. In this example, the CFET structure 310 is used to implement the inverter multiplexer in FIG. 4A. FIG. 6A shows a top view of the CFET structure 310 looking in the direction 305 in FIG. 3A, and FIG. 6B shows a bottom view of the CFET structure 310 looking in the direction 308 in FIG. 3B. Note that the reference numbers of the sources/drains are not shown in FIGS. 6A and 6B for ease of illustration.

In this example, the CFET structure 310 includes a first single diffusion break (SDB) 610 between the gates 312 and 314, a second SDB 612 between the gates 314 and 316, a third SDB 614 between the gates 316 and 318, and a fourth SDB 616 between the gates 318 and 320. In this example, the SDBs 610, 612, 614, and 616 and the gates 312, 314, 316, 318, and 320 are uniformly spaced from one another apart in the x direction by one CPP.

In this example, the gate 312 is coupled to the first input A and provides the shared gate for the first PFET 412 and the second NFET 424, and the gate 320 is coupled to the second input B and provides the shared gate for the third PFET 416 and the fourth NFET 428. The gate 316 is coupled to the select input S and provides a shared gate for the second PFET 414 and the third NFET 426.

The gate 318 is coupled to the inverse select input S̅ and provides the gate for the fourth PFET 418. In this example, the gate 318 is not used for any of the NFETs in the inverter multiplexer and is electrically isolated from the third NFET 426 and the fourth NFET 428 by the SDBs 614 and 616. The gate 314 is coupled to the inverse select input S̅ and provides the gate for the first NFET 422. In this example, the gate 314 is not used for any of the PFETs in the inverter multiplexer and is electrically isolated from the first PFET 412 and the second PFET 414 by the SDBs 610 and 612.

In this example, the first PFET 412 is coupled to the second PFET 414 by signal routing in metal layer M0 (represented by arrow 630) that extends (i.e., jumps) over the gate 314 and the SDBs 610 and 612. The second PFET 414 is coupled to the fourth PFET 418 by signal routing in metal layer M0 (represented by arrow 632) that extends over the SDB 614, and the fourth PFET 418 is coupled to the third PFET 416 by signal routing in metal layer M0 (represented by arrow 634) that extends over the SDB 616.

In this example, the third NFET 426 is coupled to the fourth NFET 428 by signal routing in backside metal layer BM0 (represented by arrow 640) that extends under the gate 318 and the SDBs 614 and 616. The third NFET 426 is coupled to the first NFET 422 by signal routing in backside metal layer BM0 (represented by arrow 642) that extends under the SDB 612, and the first NFET 422 is coupled to the second NFET 424 by signal routing in backside metal layer B0 (represented by arrow 644) that extends under over the SDB 610.

In this example, the SDBs 610, 612, 614, and 616 and the signal routing allow the CFET structure 310 to implement cross-couple gate inputs for implementing the inverter multiplexer. However, the SDBs 610, 612, 614, and 616 significantly increase the length needed for the cross-couple gate inputs from 2 CPP for the side-by-side layout 210 to 7 CPP, as shown in FIG. 6B. The significantly increased length needed for the cross-coupled gate inputs may significantly reduce or negate the area saving benefit of using the CFET structure 310. Accordingly, more area efficient techniques for implementing cross-couple gate inputs in a CFET structure are desirable.

To address the above, aspects of the present disclosure provide a structure that includes a bottom gate for the bottom diffusion region (e.g., the second diffusion region 340) in a CFET structure and an insulator (e.g., dielectric) disposed above the bottom gate for electrically isolating the top diffusion region (e.g., the first diffusion region 330) in the CFET structure from the bottom gate. Aspects of the present disclosure also provide a structure that includes a top gate for the top diffusion region (e.g., the first diffusion region 330) in the CFET structure and an insulator (e.g., dielectric) disposed below the top gate for electrically isolating the bottom diffusion region (e.g., the second diffusion region 340) in the CFET structure from the top gate. As discussed further below, these structures allow the implementation of cross-couple gate inputs in the CFET structure with high area efficiency.

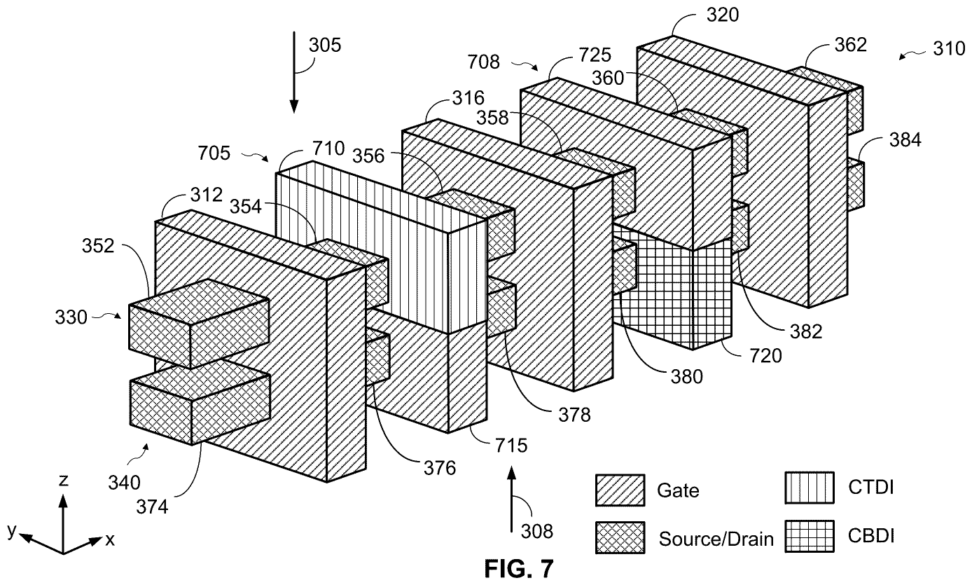

FIG. 7 shows an example of the CFET structure 310 in which the gate 314 is replaced with a first structure 705 and the gate 318 is replaced with a second structure 708 according to certain aspects. As discussed further below, the structures 705 and 708 facilitate implementation of cross-couple gate inputs in the CFET structure 310 with high area efficiency.

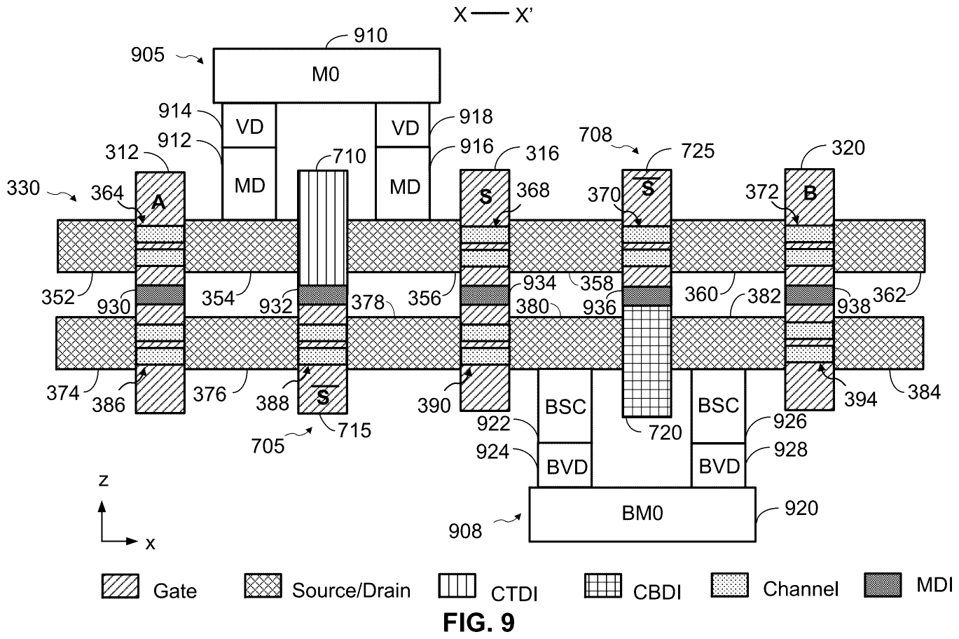

In this example, the first structure 705 includes a bottom gate 715 disposed between the source/drain 376 and the source/drain 378 of the second diffusion region 340 (i.e., the bottom diffusion region in this example). The one or more channels 388 (shown in FIG. 3B) are coupled between the source/drain 376 and the source/drain 378 and pass through the bottom gate 715 (shown in FIG. 9). The one or more channels 388 may include one or more nanosheets or another type of channel.

The first structure 705 also includes an insulator 710 disposed above the bottom gate 715 and between the source/drain 354 and the source/drain 356. The insulator 710 electrically isolates the source/drain 354 and the source/drain 356 from the bottom gate 715. Note that the insulator 710 replaces the top portion of the gate 314 and the one or more channels 366 shown in FIG. 3B. The insulator 710 may include one or more dielectric materials. The insulator 710 provides an electrical barrier between the source/drain 354 and the source/drain 356 with no channel coupled between the source/drain 354 and the source/drain 356. In FIG. 7, the insulator 710 is labeled CTDI for CFET top device isolation.

The insulator 710 may be formed during frontside processing using lithographic and etching processes. For example, the top portion of the gate 314 (shown in FIG. 3A) and the one or more channels 366 (shown in FIG. 3B) may be etched away from the top using lithographic and etching processes. The space created by the etch may then be filled with one or more dielectric materials to form the insulator 710. The insulator 710 may be formed before formation of the topside layers 105 (shown in FIGS. 1A, 1D, and 1E).

In this example, the second structure 708 includes a top gate 725 disposed between the source/drain 358 and the source/drain 360 of the first diffusion region 330 (i.e., the top diffusion region in this example). The one or more channels 370 (shown in FIG. 3B) are coupled between the source/drain 358 and the source/drain 360 and pass through the top gate 725 (shown in FIG. 9). The one or more channels 370 may include one or more nanosheets or another type of channel.

The second structure 708 also includes an insulator 720 disposed below the top gate 725 and between the source/drain 380 and the source/drain 382. The insulator 720 electrically isolates the source/drain 380 and the source/drain 382 from the top gate 725. Note that the insulator 720 replaces the bottom portion of the gate 318 and the one or more channels 392 shown in FIG. 3B. The insulator 720 may include one or more dielectric materials. The insulator 720 provides an electrical barrier between the source/drain 380 and the source/drain 382 with no channel coupled between the source/drain 380 and the source/drain 382. In FIG. 7, the insulator 720 is labeled CBDI for CFET bottom device isolation.

The insulator 720 may be formed during backside processing using lithographic and etching processes. For example, the bottom portion of the gate 318 (shown in FIG. 3A) and the one or more channels 392 (shown in FIG. 3B) may be etched away from the backside using lithographic and etching processes. The space created by the etch may then be filled with one or more dielectric materials to form the insulator 720. The insulator 720 may be formed before formation of the backside layers 155 (shown in FIGS. 1D and 1E).

In this example, the gate 316 is located between the first structure 705 and the structure 708 in the x direction. The gate 316 also be referred to as a common gate since the gate 316 is common to (i.e., shared by) the first diffusion region 330 and the second diffusion region 340. The one or more channels 368 (shown in FIG. 3B) are coupled between the source/drain 356 and the source/drain 358 and pass through the gate 316. The one or more channels 390 (shown in FIG. 3B) are coupled between the source/drain 378 and the source/drain 380 and pass through the gate 316.

It is to be appreciated that the first structure 705 and the second structure 708 are not limited to the exemplary locations shown in the example in FIG. 7. For example, in another implementation, the locations of the first structure 705 and the second structure 708 may be swapped in which the first structure 705 replaces the gate 318 and the second structure 708 replaces the gate 314 shown in FIG. 3A. In both implementations, the gate 316 is located between the first structure 705 and the second structure 708.

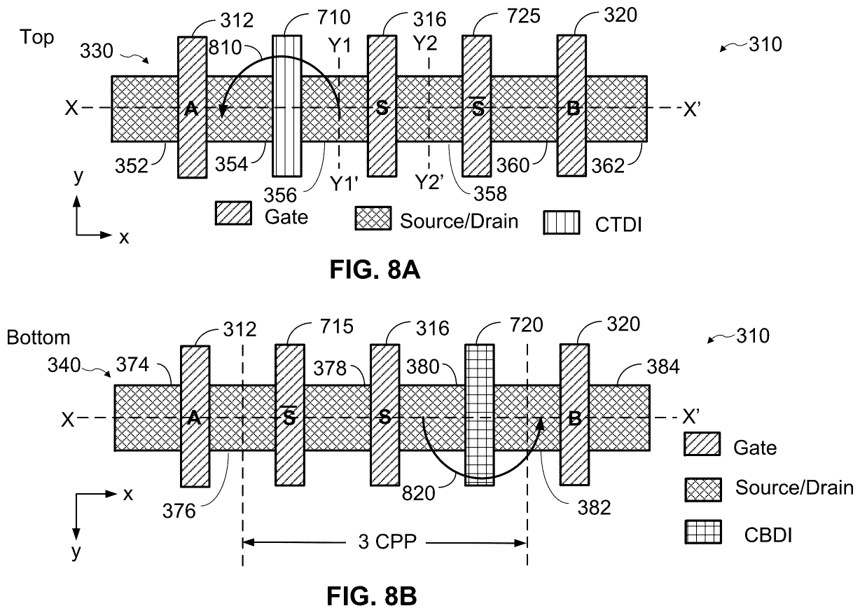

FIGS. 8A and 8B show an example in which the exemplary CFET structure 310 shown in FIG. 7 is used to implement cross-couple gate inputs for the exemplary inverter multiplexer shown in FIG. 4A. FIG. 8A shows a top view of the CFET structure 310 looking in the direction 305 in FIG. 7, and FIG. 8B shows a bottom view of the CFET structure 310 looking in the direction 308 in FIG. 7.

In this example, the gate 312 is coupled to the first input A and provides the shared gate for the first PFET 412 and the second NFET 424, and the gate 320 is coupled to the second input B and provides the shared gate for the third PFET 416 and the fourth NFET 428. The gate 316 is coupled to the select input S and provides a shared gate (i.e., common gate) for the second PFET 414 and the third NFET 426.

The bottom gate 715 is coupled to the inverse select input S̅ and provides the gate for the first NFET 422. In this example, the bottom gate 715 is electrically isolated from the first diffusion region 330 (i.e., the top diffusion region in this example) by the insulator 710. The top gate 725 is coupled to the inverse select input S̅ and provides the gate for the fourth PFET 418. In this example, the top gate 725 is electrically isolated from the second diffusion region 340 (i.e., the bottom diffusion region in this example) by the insulator 720.

In this example, the source/drain 352, the gate 312, and the source/drain 354 provide the source, the gate, and the drain, respectively, of the first PFET 412. The source/drain 356, the gate 316, and the source/drain 358 provide the source, the gate, and the drain, respectively, of the second PFET 414. The source/drain 356 is coupled to the source/drain 354 by signal routing in metal layer M0 (represented by arrow 810) in order to couple the source of the second PFET 414 to the drain of the first PFET 412. The signal routing extends over the insulator 710.

The source/drain 358, the top gate 725, and the source/drain 360 provide the drain, the gate, and the source, respectively, of the fourth PFET 418. The source/drain 360, the gate 320, and the source/drain 362 provide the drain, the gate, and the source, respectively, of the third PFET 416.

In this example, the source/drain 374, the gate 312, and the source/drain 376 provide the source, the gate, and the drain, respectively, of the second NFET 424. The source/drain 376, the bottom gate 715, and the source/drain 378 provide the source, the gate, and the drain, respectively of the first NFET 422. The source/drain 378, the gate 316, and the source/drain 380 provide the drain, the gate, and the source, respectively, of the third NFET 426. The source/drain 382, the gate 320, and the source/drain 384 provide the drain, the gate, and the source, respectively, of the fourth NFET 428. The source/drain 380 is coupled to the source/drain 382 by signal routing in backside metal layer BM0 (represented by arrow 820) in order to couple the source of the third NFET 426 to the drain of the fourth NFET 428. The signal routing extends under the insulator 720.

As shown in FIG. 8B, the first structure 705 and the second structure 708 allow for the implementation of cross-couple gate inputs in the CFET structure 310 with a length of 3 CPP. This is a significant improvement over the 7 CPP needed for the approach illustrated in FIGS. 6A and 6B, which uses SDBs. Thus, the first structure 705 and the second structure 708 provide for a much more area-efficient implementation of cross-couple gate inputs in the CFET structure 310.

FIG. 9 shows a cross-sectional view of the CFET structure 310 taken along cross-section line X-X′ in FIGS. 8A and 8B. In this example, the chip 100 includes a first jumper 905 for coupling the source/drain 354 and the source/drain 356. In this example, the first jumper 905 provides the signal routing represented by the arrow 810 in FIG. 8A. The first jumper 905 includes a first topside contact 912 (e.g., MD in FIGS. 1A, 1D, and 1E) disposed on a top surface of the source/drain 354, a second topside contact 916 (e.g., MD in FIGS. 1A, 1D, and 1E) disposed on a top surface of the source/drain 356, an interconnect 910 extending over the insulator 710 in the x direction, a first via 914 (e.g., VD in FIG. 1A. 1D, and 1E) coupled between the first topside contact 912 and the interconnect 910, and a second via 918 (e.g., VD in FIGS. 1A, 1D, and 1E) coupled between the second topside contact 916 and the interconnect 910. The interconnect 910 may be formed in topside metal layer M0.

In this example, the chip 100 also includes a second jumper 908 for coupling the source/drain 380 and the source/drain 382. In this example, the second jumper 908 provides the signal routing represented by the arrow 820 in FIG. 8B. The second jumper 908 includes a first backside contact 922 (e.g., BSC in FIGS. 1D and 1E) disposed on a bottom surface the source/drain 380, a second backside contact 926 (e.g., BSC in FIGS. 1D and 1E) disposed on a bottom the source/drain 382, an interconnect 920 extending under the insulator 720 in the x direction, a first backside via 924 (e.g., BVD in FIG. 1E) coupled between the first backside contact 922 and the interconnect 920, and a second backside via 928 (e.g., BVD in FIG. 1E) coupled between the second backside contact 926 and the interconnect 920. The interconnect 920 may be formed in backside metal layer BM0.

In certain aspects, the CFET structure 310 may also include middle dielectric isolations (MDIs) 930, 932, 934, 936, and 938. An MDI may be used in a CFET to separate the one or more channels of a bottom device from the one or more channels of a top device stacked above the bottom device. In the example shown in FIG. 9, the MDI 930 is disposed between the one or more channels 364 and the one or more channels 386, the MDI 934 is disposed between the one or more channels 368 and the one or more channels 390, and the MDI 938 is disposed between the one or more channels 372 and the one or more channels 394. In this example, each of the gates 312, 316, and 320 surrounds the respective channels and MDI. In the structure 705, the insulator 710 may be formed on top of the MDI 932 with the one or more channels 388 below the MDI 932. In the structure 708, the insulator 720 may be formed below the MDI 936 with the one or more channels 370 above the MDI 936. Note that the MDIs are not shown in FIG. 7.

Although aspects of the present disclosure are discussed above using the example on the inverter multiplexer shown in FIG. 4A, it is to be appreciated that the CFET structure 310 may be used to implement other types of logic gates and sequential logic (e.g., flip-flops) with cross-couple gate inputs. In general, the gate 312 is coupled to a first gate input, the gate 320 is coupled to a second gate input, the gate 316 (which is between the structures 705 and 708) is coupled to a third gate input, and the bottom gate 715 and the top gate 725 are coupled to a fourth gate input (i.e., the bottom gate 715 is coupled to the top gate 725). For the example of the inverter multiplexer shown in FIG. 4A, the first gate input, the second gate input, the third gate input, and the fourth gate input correspond to the first input A, the second input B, the select input S, and the inverse select input S̅, respectively. To implement the exemplary XOR gate shown in FIG. 4B, the first gate input, the second gate input, the third gate input, and the fourth gate input may correspond to the first input A, the inverse of the first input Ā, the inverse of the second input B̅, and the second input B, respectively.

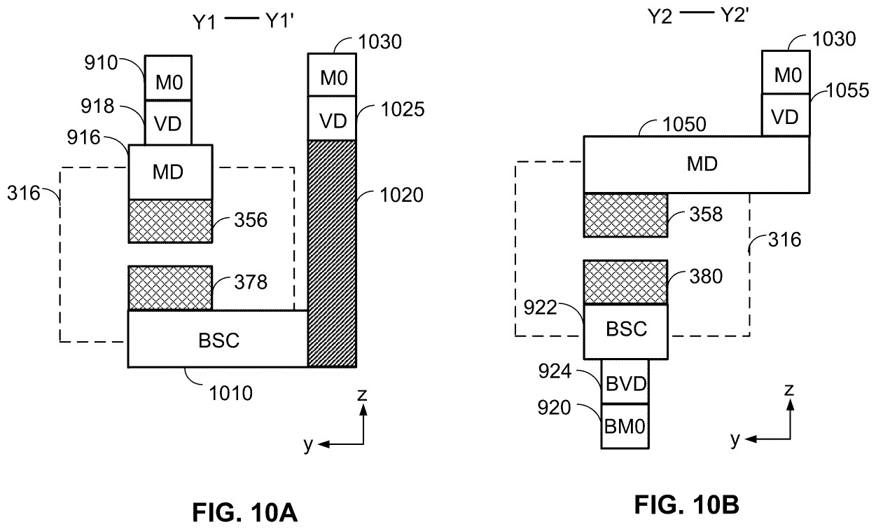

In certain aspects, the source/drain 378 and the source/drain 358 are both coupled to the output 420 (shown in FIGS. 4A and 4B) to couple the drains of the PFETs 414 and 418 and the drains of the NFETs 422 and 426 to the output 420. Thus, in this example, the source/drain 378 is coupled to the source/drain 358. FIG. 10A shows a cross-sectional view of an exemplary structure configured to couple the source/drain 378 to the output 420 taken along cross-section line Y1-Y1′ in FIG. 8A, and FIG. 10B shows a cross-sectional view of an exemplary structure configured to couple the source/drain 358 to the output 420 taken along cross-section line Y2-Y2′ in FIG. 8A.

Referring to FIG. 10A, in this example, the chip 100 includes a backside contact 1010, a vertical connector 1020, an output path 1030, and a via 1025. The output path 1030 provides the output 420 discussed above. The output path 1030 extends in the x direction and may be formed in metal layer M0.

The backside contact 1010 (e.g., BSC in FIGS. 1D and 1E) is coupled to a bottom surface of the source/drain 378 and extends in the y direction. The vertical connector 1020 is coupled to the backside contact 1010. The vertical connector 1020 extends vertically in the z direction and is coupled to the output path 1030 by the via 1025 (e.g., VD in FIGS. 1A, 1D, and 1E). Thus, in this example, the vertical connector 1020 provides vertical coupling between the backside contact 1010 and the output path 1030 in metal layer M0. The vertical connector 1020 may be formed, for example, by etching a trench and filling the trench with metal.

Referring to FIG. 10B, in this example, the chip 100 includes a topside contact 1050 and a via 1055. The topside contact 1050 (e.g., MD in FIGS. 1A, 1D, and 1E) is coupled to a top surface of the source/drain 358 and extends in the y direction. The topside contact 1050 is coupled to the output path 1030 by the via 1055 (e.g., VD in FIGS. 1A, 1D, and 1E). Note that the output path 1030 extends in the x direction between the vias 1025 and 1055.

In this example, the source/drain 352 and the source/drain 362 may be coupled to the supply rail 415. For example, the supply rail 415 may be formed in metal layer M0 and coupled to the source/drain 352 and the source/drain 362 by respective topside contacts (e.g., MD in FIGS. 1A, 1D, and 1E) and respective vias (e.g., VD in FIGS. 1A, 1D, and 1E). In this example, the source/drain 374 and the source/drain 384 may be coupled to the low rail 430 (e.g., ground rail). For example, the low rail 430 may be formed in backside metal layer BM0 and coupled to the source/drain 374 and the source/drain 384 by respective backside contacts (e.g., BSC in FIGS. 1D and 1E) and respective backside vias (e.g., BVD in FIG. 1E).

It is to be appreciated that FIGS. 10A and 10B show just one example for routing the source/drain 378 and the source/drain 358 to the output 420 and that other routing schemes may be used.

It is to be appreciated that the first diffusion region 330 (i.e., the top diffusion region) and the second diffusion region 340 (i.e., the bottom diffusion region) are not limited to the example where the first diffusion region 330 is p-type and the second diffusion region 340 is n-type. In other implementations, the first diffusion region 330 may be n-type and the second diffusion region 340 may be p-type. In this example, the first diffusion region 330 is used for the NFETs 422, 424, 426, and 428 and the second diffusion region 340 is used for the PFETs 412, 414, 416, and 418.

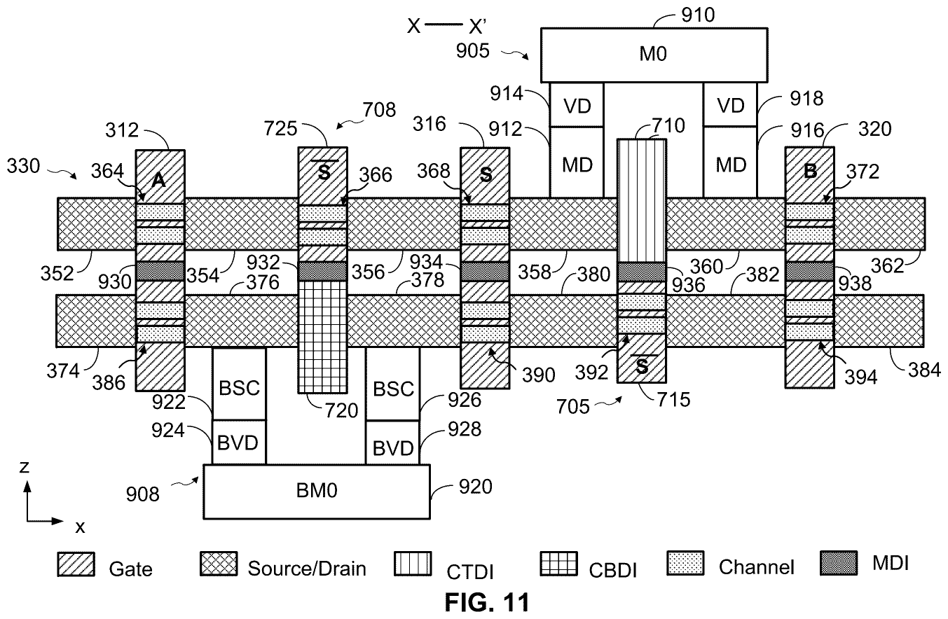

In this regard, FIG. 11 shows a cross-sectional view of the CFET structure 310 along the cross-section line X-X′ for the example in which the first diffusion region 330 is n-type and the second diffusion region 340 is p-type. In this example, the locations of the structures 705 and 708 shown in FIG. 9 are swapped.

In this example, the source/drain 352, the gate 312, and the source/drain 354 provide the source, the gate, and the drain, respectively, of the second NFET 424. The source/drain 354, the top gate 725, and the source/drain 356 provide the source, the gate, and the drain, respectively, of the first NFET 422. The source/drain 356, the gate 316, and the source/drain 358 provide the drain, the gate, and the source, respectively, of the third NFET 426. The source/drain 360, the gate 320, and the source/drain 362 provide the drain, the gate, and the source, respectively, of the fourth NFET 428. In this example, the first jumper 905 is coupled between the source/drain 358 and the source/drain 360 to couple the source of the third NFET 426 to the drain of the fourth NFET 428.

The source/drain 374, the gate 312, and the source/drain 376 provide the source, the gate, and the drain, respectively, of the first PFET 412. The source/drain 378, the gate 316, and the source/drain 380 provide the source, the gate, and the drain, respectively, of the second PFET 414. The source/drain 380, the bottom gate 715, and the source/drain 382 provide the drain, the gate, and the source, respectively, of the fourth PFET 418. The source/drain 382, the gate 320, and the source/drain 384 provide the drain, the gate, and the source, respectively, of the third PFET 416. In this example, the second jumper 908 is coupled between the source/drain 376 and the source/drain 378 to couple the drain of the first PFET 412 to the source of the second PFET 414.

In this example, the source/drain 356 and the source/drain 380 are both coupled to the output 420 (shown in FIGS. 4A and 4B) to couple the drains of the PFETs 414 and 418 and the drains of the NFETs 422 and 426 to the output 420. Thus, in this example, the source/drain 356 is coupled to the source/drain 380. In this example, the source/drain 356 may be coupled to the output 420 using the exemplary structure in FIG. 10B with the topside contact 1050 coupled to a top surface of the source/drain 356, Also, the source/drain 380 may be coupled to the output 420 using the exemplary structure in FIG. 10A with the backside contact 1010 coupled to a bottom surface of the source/drain 380.

In this example, the source/drain 352 and the source/drain 362 may be coupled to the low rail 430. For example, the low rail 430 may be formed in metal layer M0 and coupled to the source/drain 352 and the source/drain 362 by respective topside contacts (e.g., MD in FIGS. 1A, 1D, and 1E) and respective vias (e.g., VD in FIGS. 1A, 1D, and 1E). In this example, the source/drain 374 and the source/drain 384 may be coupled to the supply rail 415. For example, the supply rail 415 may be formed in backside metal layer BM0 and coupled to the source/drain 374 and the source/drain 384 by respective backside contacts (e.g., BSC in FIGS. 1D and 1E) and respective backside vias (e.g., BVD in FIG. 1E).

In both of the examples shown in FIGS. 9 and 11, the bottom gate 715 is coupled to the top gate 725 since the bottom gate 715 and the top gate 725 are both coupled to the same gate input (e.g., the inverse select input S̅). In this example, the top gate 725 may be coupled to a gate input formed in metal layer M0 by a topside contact (e.g., MD in FIGS. 1A, 1D, and 1E) and a via (e.g., VG in FIGS. 1A, 1D, and 1E). The bottom gate 715 may be coupled to the gate input in metal layer M0 by a vertical connector and a via (e.g., VG in FIGS. 1A, 1D, and 1E). The vertical connector may be similar to the vertical connector 1020 shown in FIG. 10A and may be formed using the same process as the vertical connector 1020 for process efficiency.

Implementation examples are described in the following numbered clauses:
1. A chip, comprising:
   a first source/drain;
   a second source/drain;
   a top gate disposed between the first source/drain and the second source/drain; one or more first channels coupled between the first source/drain and the second source/drain, wherein the one or more first channels pass through the top gate;
   a third source/drain, wherein the third source/drain is vertically stacked with the first source/drain;
   a fourth source/drain, wherein the fourth source/drain is vertically stacked with the second source/drain; and
   a first insulator disposed below the top gate and between the third source/drain and the fourth source/drain, wherein the first insulator electrically isolates the top gate from the third source/drain and the fourth source/drain.
2. The chip of clause 1, further comprising a jumper coupling the third source/drain to the fourth source/drain.
3. The chip of clause 2, wherein the jumper comprises:
   a first backside contact coupled to a bottom surface of the third source/drain;
   a second backside contact coupled to a bottom surface of the fourth source/drain; and
   an interconnect coupled to the first backside contact and the second backside contact, wherein the interconnect extends under the first insulator.
4. The chip of any one of clauses 1 to 3, wherein each of the first source/drain, the second source/drain, the third source/drain, and the fourth source/drain comprises a respective epitaxial layer.
5. The chip of any one of clauses 1 to 4, further comprising:
   a fifth source/drain;
   a sixth source/drain;
   a bottom gate disposed between the fifth source/drain and the sixth source/drain; one or more second channels coupled between the fifth source/drain and the sixth source/drain, wherein the one or more second channels pass through the bottom gate;
   a seventh source/drain, wherein the seventh source/drain is vertically stacked with the fifth source/drain;
   an eighth source/drain, wherein the eighth source/drain is vertically stacked with the sixth source/drain; and
      a second insulator disposed above the bottom gate and between the seventh source/drain and the eighth source/drain, wherein the second insulator electrically isolates the bottom gate from the seventh source/drain and the eighth source/drain.
6. The chip of clause 5, wherein the top gate is coupled to the bottom gate.
7. The chip of clause 5 or 6, further comprising:
   a first jumper coupling the third source/drain to the fourth source/drain; and
   a second jumper coupling the seventh source/drain to the eighth source/drain.
8. The chip of clause 7, wherein the first jumper includes a first interconnect extending under the first insulator, and the second jumper includes a second interconnect extending over the second insulator.
9. The chip of any one of clauses 5 to 8, wherein each of the first source/drain, the second source/drain, the third source/drain, the fourth source/drain, the fifth source/drain, the sixth source/drain, the seventh source/drain, and the eighth source/drain comprises a respective epitaxial layer.
10. The chip of any one of clauses 5 to 9, further comprising a common gate disposed between the second source/drain and the eighth source/drain and between the fourth source/drain and the sixth source/drain.
11. The chip of clause 10, further comprising:
   one or more third channels coupled between the second source/drain and the eighth source/drain, wherein the one or more third channels pass through the common gate; and
   one or more fourth channels coupled between the fourth source/drain and the sixth source/drain, wherein the one or more fourth channels pass through the common gate.
12. The chip of clause 11, further comprising a middle dielectric isolation (MDI) disposed between the one or more third channels and the one or more fourth channels.
13. The chip of any one of clauses 10 to 12, wherein the second source/drain is coupled to the sixth source/drain.
14. The chip of any one of clauses 10 to 13, further comprising a first input coupled to the common gate, and a second input coupled to the bottom gate and the top gate.
15. The chip of clause 14, wherein the second input is an inverse of the first input.
16. A chip, comprising:
   a top gate;
   a first insulator disposed below the top gate;
   a bottom gate;
   a second insulator disposed above the bottom gate;
   a common gate;
   a first source/drain disposed between the top gate and the common gate;
   a second source/drain disposed between the common gate and the second insulator;
   one or more first channels coupled between the first source/drain and the second source/drain, wherein the one or more first channels pass through the common gate;
   a third source/drain disposed between the first insulator and the common gate, wherein the third source/drain is stacked vertically with the first source/drain;
   a fourth source/drain disposed between the common gate and the bottom gate, wherein the fourth source/drain is stacked vertically with the second source/drain; and
   one or more second channels coupled between the third source/drain and the fourth source/drain, wherein the one or more second channels pass through the common gate.
17. The chip of clause 16, wherein the first source/drain is coupled to the fourth source/drain.
18. The chip of clause 16 or 17, further comprising a first input coupled to the common gate, and a second input coupled to the bottom gate and the top gate.
19. The chip of clause 18, wherein the second input is an inverse of the first input.
20. The chip of any one of clauses 16 to 19, wherein the top gate is coupled to the bottom gate.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first source/drain;
a second source/drain;
a top gate disposed between the first source/drain and the second source/drain;
one or more first channels coupled between the first source/drain and the second source/drain, wherein the one or more first channels pass through the top gate;
a third source/drain, wherein the third source/drain is vertically stacked with the first source/drain;
a fourth source/drain, wherein the fourth source/drain is vertically stacked with the second source/drain; and
a first insulator disposed below the top gate and between the third source/drain and the fourth source/drain, wherein the first insulator electrically isolates the top gate from the third source/drain and the fourth source/drain.

2. The chip of claim 1, further comprising a jumper coupling the third source/drain to the fourth source/drain.

3. The chip of claim 2, wherein the jumper comprises:
a first backside contact coupled to a bottom surface of the third source/drain;
a second backside contact coupled to a bottom surface of the fourth source/drain; and
an interconnect coupled to the first backside contact and the second backside contact, wherein the interconnect extends under the first insulator.

4. The chip of claim 1, wherein each of the first source/drain, the second source/drain, the third source/drain, and the fourth source/drain comprises a respective epitaxial layer.

5. The chip of claim 1, further comprising:
a fifth source/drain;
a sixth source/drain;
a bottom gate disposed between the fifth source/drain and the sixth source/drain;
one or more second channels coupled between the fifth source/drain and the sixth source/drain, wherein the one or more second channels pass through the bottom gate;
a seventh source/drain, wherein the seventh source/drain is vertically stacked with the fifth source/drain;
an eighth source/drain, wherein the eighth source/drain is vertically stacked with the sixth source/drain; and
a second insulator disposed above the bottom gate and between the seventh source/drain and the eighth source/drain, wherein the second insulator electrically isolates the bottom gate from the seventh source/drain and the eighth source/drain.

6. The chip of claim 5, wherein the top gate is coupled to the bottom gate.

7. The chip of claim 5, further comprising:
a first jumper coupling the third source/drain to the fourth source/drain; and
a second jumper coupling the seventh source/drain to the eighth source/drain.

8. The chip of claim 7, wherein the first jumper includes a first interconnect extending under the first insulator, and the second jumper includes a second interconnect extending over the second insulator.

9. The chip of claim 5, wherein each of the first source/drain, the second source/drain, the third source/drain, the fourth source/drain, the fifth source/drain, the sixth source/drain, the seventh source/drain, and the eighth source/drain comprises a respective epitaxial layer.

10. The chip of claim 5, further comprising a common gate disposed between the second source/drain and the eighth source/drain and between the fourth source/drain and the sixth source/drain.

11. The chip of claim 10, further comprising:
one or more third channels coupled between the second source/drain and the eighth source/drain, wherein the one or more third channels pass through the common gate; and
one or more fourth channels coupled between the fourth source/drain and the sixth source/drain, wherein the one or more fourth channels pass through the common gate.

12. The chip of claim 11, further comprising a middle dielectric isolation (MDI) disposed between the one or more third channels and the one or more fourth channels.

13. The chip of claim 10, wherein the second source/drain is coupled to the sixth source/drain.

14. The chip of claim 10, further comprising a first input coupled to the common gate, and a second input coupled to the bottom gate and the top gate.

15. The chip of claim 14, wherein the second input is an inverse of the first input.

16. A chip, comprising:
a top gate;
a first insulator disposed below the top gate;
a bottom gate;
a second insulator disposed above the bottom gate;
a common gate;
a first source/drain disposed between the top gate and the common gate;
a second source/drain disposed between the common gate and the second insulator;
one or more first channels coupled between the first source/drain and the second source/drain, wherein the one or more first channels pass through the common gate;
a third source/drain disposed between the first insulator and the common gate, wherein the third source/drain is stacked vertically with the first source/drain;
a fourth source/drain disposed between the common gate and the bottom gate, wherein the fourth source/drain is stacked vertically with the second source/drain; and
one or more second channels coupled between the third source/drain and the fourth source/drain, wherein the one or more second channels pass through the common gate.

17. The chip of claim 16, wherein the first source/drain is coupled to the fourth source/drain.

18. The chip of claim 16, further comprising a first input coupled to the common gate, and a second input coupled to the bottom gate and the top gate.

19. The chip of claim 18, wherein the second input is an inverse of the first input.

20. The chip of claim 16, wherein the top gate is coupled to the bottom gate.
